(19) United States
(12) Patent Application Publication
(10) Pub. No.: US 2018/0313697 A1
(43) Pub. Date: Nov. 1, 2018

(54) PROCESS MONITORING DEVICE

(71) Applicant: NOVENA TEC INC., Markham (CA)

(72) Inventors: Rommel MONTES, Alberta (CA); Ravi THIRUN, Markham (CA); Rajan THIRU, Markham (CA)

(73) Assignee: NOVENA TEC INC., Markham, ON (CA)

(21) Appl. No.: 15/769,255

(22) PCT Filed: Oct. 19, 2016
(86) PCT No.: PCT/CA2016/051211

§ 371 Date: Apr. 18, 2018

Related U.S. Application Data
(60) Provisional application No. 62/243,363, filed on Oct. 19, 2015.

(51) Int. Cl. G01K 1/10; G01K 1/02; H01L 21/67; H01L 21/683; H02J 7/02

(52) U.S. Cl. CPC G01K 1/10; G01K 1/024; H01L 21/67248; H01L 35/00; H01L 21/6831; H02J 7/025; H01L 21/67253

(57) ABSTRACT

A process chamber measurement wafer for location inside a process chamber and measuring environmental conditions within the process chamber during a process run. The process chamber measurement wafer including a releasable dummy wafer to protect the instrumented portion of the process chamber measurement wafer from process material deposited during the process run.

### CROSS-REFERENCE TO RELATED APPLICATION

This application claims priority to U.S. Provisional Patent Application Ser. No. 62/243,363 filed on Oct. 19, 2016, the contents of which are incorporated entirely herein by reference.

### FIELD

The present application relates to the manufacture of semiconductor wafers, and more particularly to a process monitoring device for measuring process conditions inside a plasma process chamber and transmitting data outside the chamber using the same.

### BACKGROUND

Variations in fabrication processing used in the semiconductor industry impact product quality and performance. Processes such as etching, coating, baking, deposition, growing and masking need to be controlled precisely and optimized to ensure uniform, high quality product. Even minor deviations from optimum process conditions can significantly impact operability of the product.

Plasma process chambers are used to deposit material during the manufacture of semiconductor wafers. In general, the three main parameters inside the process chamber that affect deposition are temperature, plasma density, and pressure. The plasma density and chamber pressure variables are typically maintained under tight control within the plasma process chamber. Temperature, however can vary within the chamber, which can lead to unequal deposition of material onto a wafer being processed.

The standard technique for evaluating a process temperature profile within a process chamber is by offline indirect measurement. In the technique, a dummy wafer is run through the process chamber, and then sent for offline thickness measurement of the resulting deposition. Variation in temperature leads to variation in deposition thickness on a processed wafer. After evaluation of the deposition thickness on the dummy wafer, adjustments can be made to the process chamber set-up to try to achieve a desired temperature profile within the chamber. This technique is typically repeated iteratively until the process can consistently produce dummy wafers with deposition within tolerance.

The standard technique raises a number of problems in the manufacture of semiconductor wafers. First, the iterative process is time consuming and expensive as the process adjustments must wait for the offline thickness measurements to be made. Second, the available adjustments for the process chamber are somewhat coarse, and it can be time consuming to find the correct combination of heater and coolant settings necessary to provide a chamber temperature profile within acceptable tolerance. Measuring the thickness of deposition on a processed dummy wafer is an indirect measurement of the temperature profile, complicating which process adjustments are appropriate to correct the temperature profile.

Alternatively, a sensor device can be included in the process chamber to directly monitor the conditions the substrate is experiencing. Sensor devices may be of the same or similar shape, size and material as the substrate to more accurately measure the conditions the substrate experiences. Prior instrumented wafers, also called Process Condition Measuring Device (PCMD), include those by KLA-Tencor for measuring various parameters such as temperature and pressure. As the sensor devices used in situ are subject to conditions in the plasma chamber, these devices are prone to damage that impacts functionality and accuracy of the devices for multiple uses.

Accordingly, there is a need for an improved system, device, and method for conducting the setup and monitoring of a plasma process chamber. Moreover, there is a need for accurate, stable, and long lasting measuring devices.

This background information is provided for the purpose of making known information believed by the applicant to be of possible relevance to the present invention. No admission is necessarily intended, nor should be construed, that any of the preceding information constitutes prior art against the present invention.

### SUMMARY

An object of the present invention is to provide a process monitoring device and method for measuring process conditions using the same. In accordance with an aspect of the present invention, there is provided a process chamber measurement wafer comprising a dummy wafer releasably coupled to an instrumented wafer; the instrumented wafer comprising one or more sensors, a wireless communication module and a battery module and optional on board memory storage.

In accordance with another aspect, there is provided a process chamber measurement wafer comprising a dummy wafer electrostatically coupled to an instrumented wafer; the instrumented wafer comprising a first layer comprising a dielectric plate for electrostatically coupling to the dummy wafer and a second layer comprising an instrumented plate; wherein the instrumented plate comprises one or more sensors, wireless communication module and battery module and optional on board memory storage.

In accordance with another aspect, there is provided an instrumented wafer comprising a first layer comprising a dielectric plate for electrostatically coupling a dummy wafer to the instrumented wafer and a second layer comprising an instrumented plate; wherein the instrumented plate comprises one or more sensors, wireless communication module and battery module and optional on board memory storage.

In accordance with an aspect of the present invention, there is provided a kit containing an instrumented wafer comprising one or more sensors, a wireless communication module and a battery module and optional on board memory storage, and a plurality of dummy wafers each adapted to releasably couple to a face of the instrumented wafer.

### BRIEF DESCRIPTION OF THE FIGURES

These and other features will become more apparent in the following detailed description in which reference is made to the appended drawings.

FIG. 1 is a cross-sectional simplified view of an embodiment of a process measurement device.

FIG. 2 is a block diagram of the instrumented wafer component of the process measurement device according to one embodiment

FIG. 3 is a cross-sectional simplified diagram representing an embodiment of a process measurement device in place on a charging station.

FIG. 4 is a simplified top sectional view representing an embodiment of a process measurement device.

FIG. 5 is a simplified cross-sectional view of an embodiment of a process measurement device.

FIG. 6 is a simplified close-up cross-sectional view of a portion of the process measurement device of FIG. 5.

FIG. 7 is a simplified isometric sectional view of the section of FIG. 5.

FIG. 8 is a simplified isometric top sectional view of an instrumented wafer portion of a process measurement device.

FIG. 9 is a simplified isometric top sectional view of a process measurement device.

### DETAILED DESCRIPTION

In an implementation, the process measurement device comprises a process chamber measurement wafer is similar or substantially the same in shape and size as a substrate used in the manufacture of semiconductor wafers and is configured to measure during operation of a process chamber at least one process condition at one or more locations on the wafer and to store and/or transmit the condition data to a receiver outside the process chamber. The shape, size and thickness of the process chamber measurement wafer can be varied according to the size of wafer used in the process chamber.

In an implementation a temperature sensing ceramic wafer assembly is provided. The ceramic wafer assembly including two protective chemical-resistant ceramic plates, sandwiched to protect an electronics package including temperature acquisition and transmission circuitry contained within the assembly. In an aspect, the wafer assembly has temperature sensors located to measure temperature on top and bottom surfaces of the wafer assembly, to enable simultaneously temperature measurements above and below the ceramic wafer assembly. In an aspect, the temperature measurements are of the pedestal and the plasma in the process chamber, when the wafer assembly is located with a bottom surface resting on the pedestal.

In an aspect the wafer assembly further includes an electrostatic chuck located on one or both sides of the wafer. The electrostatic chuck including a first conductive layer embedded in a dielectric body and another conductive layer between the first conductive layer, and the electronics package. In an aspect the electronics package is thermally insulated. The thermal insulation may be selected from the group consisting of Aluminum foil and Aerogel.

In an implementation, the wafer assembly includes a releasable protective layer over a top surface. The releasable protective layer may be coupled to the top surface using electroadhesion. In an aspect, the protective layer may be made from silicon, ceramic or polymer.

In an implementation, a method of measuring a process condition within a process chamber. The method comprising: locating an instrumented wafer to electrically couple a connector of the instrumented wafer to a high voltage supply of the charging station and to electrically couple a ground plane of the instrumented wafer to an electrical ground; energizing the high voltage supply to electrostatically couple a dummy wafer over a top surface of the instrumented wafer to produce a process chamber measurement wafer; decoupling the connector from the high voltage supply; locating the process chamber measurement wafer in a process chamber; executing a process run of the process chamber, and collecting measurements of at least one process condition within the process chamber using the instrumented wafer; after the process run has completed, removing the process chamber measurement wafer from the process chamber; locating the process chamber measurement wafer to electrically couple the connector of the instrumented wafer to the high voltage supply and to electrically couple the ground plane of the instrumented wafer to the electrical ground; and, matching the voltage of the connector and the ground plane using the charging station to release the dummy wafer from the instrumented wafer.

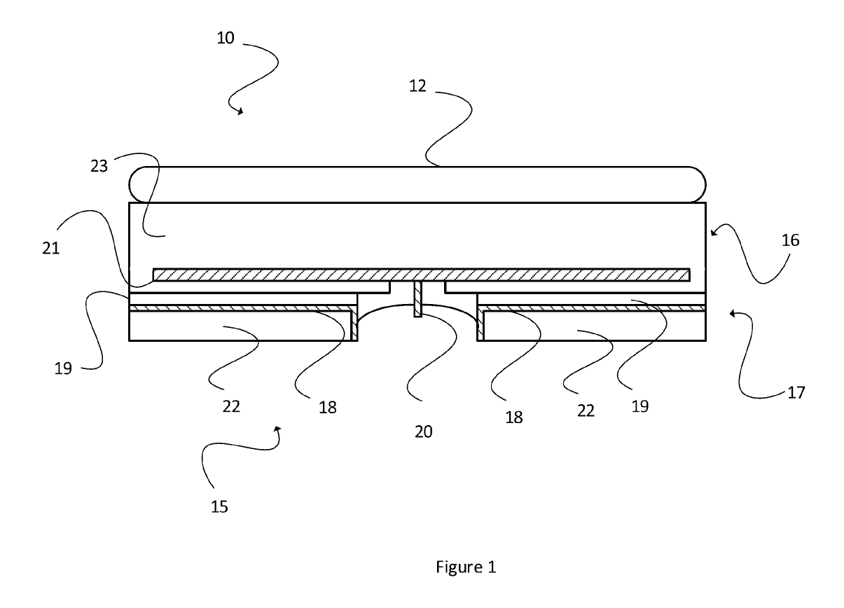

Referring to FIG. 1, a simplified, non-scale, sectional view of a process chamber measurement wafer 10 is presented. In particular, the view illustrates components whose size is overly exaggerated vertically for clarity of description. Some components and features are also drawn out of scale to provide for identification and explanation of their function.

The process chamber measurement wafer 10 is a multi-layer construction and comprises a thin removable dummy wafer 12 and a sealed instrumented wafer 15. The dummy wafer 12 is releasably coupled to the top surface of the instrumented wafer 15 and acts as a protective layer over the instrumented wafer 15 during exposure in the process chamber and receives deposition of material during operation of the process chamber without severely damaging the underlying instrumented wafer 15. The dummy wafer 12 is optionally manufactured from a suitable substrate material used in the manufacture of semiconductor wafers including, for instance, silicon, ceramic or polymer.

During refurbishment of the process chamber measurement wafer, the dummy wafer 12 is decoupled from the instrumented wafer 15 and replaced with a replacement dummy wafer 12. The dummy wafer 12 may be releasably coupled to the instrumented wafer 15 by a variety of methods including adhesion, spot welding, fastening, and the like. In an aspect, the dummy wafer 12 is releasably coupled to the instrumented wafer 15 by electroadhesion. In such embodiments, the dummy wafer 12 may be replaced after deactivating the electrostatic adhesive function in the instrumented wafer 15 to release the dummy wafer 12. A replacement dummy wafer 12 may be introduced after removing the released dummy wafer 12.

For embodiments of the process chamber measurement wafer 10 that use electroadhesion to couple the dummy wafer 12 to the instrumented wafer 15, the instrumented wafer 15 may be considered to comprise two layers, a coupling layer 16 and an instrument package layer 17. The coupling layer 16 including an electrostatic chuck 21, which may comprise a printed electrode sandwiched within a suitable dielectric material 23, such as a dielectric ceramic. A high-voltage connector 20 extends from the printed electrode 21 to the exterior of the back side of the instrumented wafer 15 to provide an electrical connection to the electrostatic chuck 21.

The instrument package layer 17 contains the electronics and power source for the process chamber measurement wafer 10. The instrument package layer 17 may generally comprise a dielectric insulating layer 19 that separates the instrument package layer 17 from the coupling layer 16. Depending upon the construction method employed, the dielectric insulating layer 19 may be in direct contact with the electrostatic chuck 21. Alternatively, the dielectric insulating layer 19 may be separated from the electrostatic chuck 21 by another layer, such as an adhesive layer, or another electrically insulating layer.

Below the insulating layer 19 is a metallized layer 18 that isolates the electronics from the electrostatic chuck 21 and the high voltage connector 20. The metallized layer 18 acts as a grounding plane 18 when it is connected to an electrical ground. A dielectric insulating layer 19 separates the metallized layer 18 from the electrostatic chuck 21. In some aspects, the dielectric insulating layer 19 may be formed over the metallized layer 18 before connecting the instrument package layer 17 with the coupling layer 16. In some aspects, the dielectric layer 18 may be formed in the coupling layer 16, and the metallized layer 18 may comprise a top layer of the instrumented wafer 15. In general, the electrostatic chuck 21 is separated from the metallized layer 18 by an electrically insulating layer, whether that layer is considered to be a single layer or a bonded pair of layers that separately define the top surface of the instrument package layer 17 and the bottom surface of the coupling layer 16.

The payload volume 22 of the instrument package layer 17 contains the electronics, and may be formed from suitable material to support and protect the electronics within the process chamber during process operations. The electronics within the payload volume 22 may be surrounded by a thermal insulating layer, such as an Aluminum foil infrared reflection layer or an Aerogel, to provide thermal insulation from the process chamber. Accordingly, the instrumented wafer 15 is configured to provide protection for an electronics package, that is resistant to high temperatures, including up to 500° C. in the process chamber.

A process chamber measurement wafer 10 may be manufactured by a variety of methods. An exemplary method of manufacture, where the instrumented wafer 10 is constructed of two separate parts which are then combined, is recited in detail immediately below. An alternate exemplary method of manufacture, where the instrumented wafer 10 is constructed as a single layered part, is recited further below. As will be appreciated, these methods of manufacture, while advantageous by balancing cost of manufacture against performance of end product, are only examples of methods that may be used to produce the instrumented wafer 10.

In an embodiment, a method of manufacture may be provided where the instrumented wafer 15 may be conveniently assembled in two parts, the coupling layer 16 and the instrument package layer 17.

The completed parts may then be assembled to complete the instrumented wafer 15. In an implementation, the coupling layer 16 may be formed by printing a metal electrode onto a dielectric 23. The printed metal electrode providing the electrostatic chuck 21 once the instrumented wafer 15 is completed. An insulating adhesive, and/or an additional dielectric layer, may be applied to the exposed surface of the electrode.

The instrument package layer 17 may be formed by metallizing a top surface and exposed sidewall of the payload volume 22 to create a metallized layer 18. The metallized layer 18 to provide a ground plane when acting in coordination with the electrostatic chuck 21.

An insulating dielectric 19 may be bonded to the metallized top surface. As explained above, in an alternate configuration the insulating dielectric 19 may form part of the coupling layer 16, to be placed next to the metallized layer 18 when the coupling layer 16 and the instrument package layer 17 are combined together.

The insulating dielectric 19 of the instrument package layer 17 may then be bonded to the bottom surface of the coupling layer 16 to attach the instrument package layer 17 to the coupling layer 16. The two layers may be bonded, for instance by an adhesive bond and/or mechanical attachments. The high voltage connector 20 may be connected to the electrostatic chuck, for instance by soldering, crimping, pressing, forming, or other suitable connection means. An insulating adhesive may be applied as necessary to bond and seal the seams between the coupling layer 16 and the instrument package layer 17. In an implantation the bodies of the instrument package layer 17 and the coupling layer 16 may be formed from a suitable wafer material. In an aspect, the wafer material comprises ceramic, with cavities within the ceramic to accommodate the components described above. In the implementation, completing the assembly of the coupling layer 16 to the instrument package layer 17 produces a ceramic instrumented wafer 15. The dummy wafer 12 may similarly be formed of a suitable wafer material. In an aspect, the dummy wafer 12 may be formed of a ceramic.

In an alternate method of manufacture, the metallized layer 18, the insulating layer 19, and the electrostatic chuck 21 are formed directly onto the payload volume 22 of the instrument package layer 17. In this method, the insulating layer 19 may comprise a ceramic insulating layer 19. In other methods, different materials as known in the art may be used to form the insulating layer 19.

For example, in a first step electrode traces for the metallized layer 18 (along with ground connections) are patterned onto the payload volume 22. In a second step, the metallized layer 18 may then be electrically insulated by application of a dielectric layer 19 to the metallized layer 18 (e.g. by application of a ceramic dielectric coating layer either in a sheet format or as a coating). The electrical insulation step may be performed in several ways, including the methods listed below. The electrostatic chuck 21 may then be bonded to the dielectric layer 19.

The electrical insulation step may vary, depending upon, for instance where the dielectric insulating layers are ceramic, whether: a) a solid ceramic sheet is used as an insulating layer; b) a ceramic coating layer is used as an insulating layer; or, c) a combination of a solid ceramic sheet and a ceramic coating layer are used as an insulating layer. As will be appreciated, similar options are available where different dielectric materials are used.

Where a solid ceramic sheet is used as an insulating layer, the electrical insulation step may be performed by: i) depositing a metallized layer (electrostatic chuck 21) on a backside of the dielectric material 23 (e.g. a solid ceramic sheet); ii) depositing a metallized layer 18 (ground plane) on the top surface of the instrument package layer 17; iii) bonding a ceramic sheet with cut-out for the connector 20 (insulating layer 19) over the metallized layer 18; and, iv) bonding the electrostatic chuck 21 to the insulating layer 19.

Where a ceramic coating layer is used, the electrical insulation step may be performed by: i) depositing a metallized layer 18 (ground plane) on the top surface of the instrument package layer 17; ii) coating the surface of the metallized layer 18 (ground plane) with a dielectric (e.g. Yttria, Alumina, Aluminum Nitride, or other suitable dielectric) as insulating layer 19; iii) depositing a metallized layer (electrostatic chuck 21) onto the insulating layer 19, including the central hole; iv) form the connector 20 onto the electrostatic chuck 21; and, v) coating the electrostatic chuck 21 with a suitable dielectric (e.g. Yttria, Alumina, Aluminum Nitride, or other suitable dielectric) as dielectric layer 23.

In some aspects, a combination of a solid sheet and a coating may be used to form the dielectric layers. For instance, either layer may comprise a sheet while the other may comprise a coating.

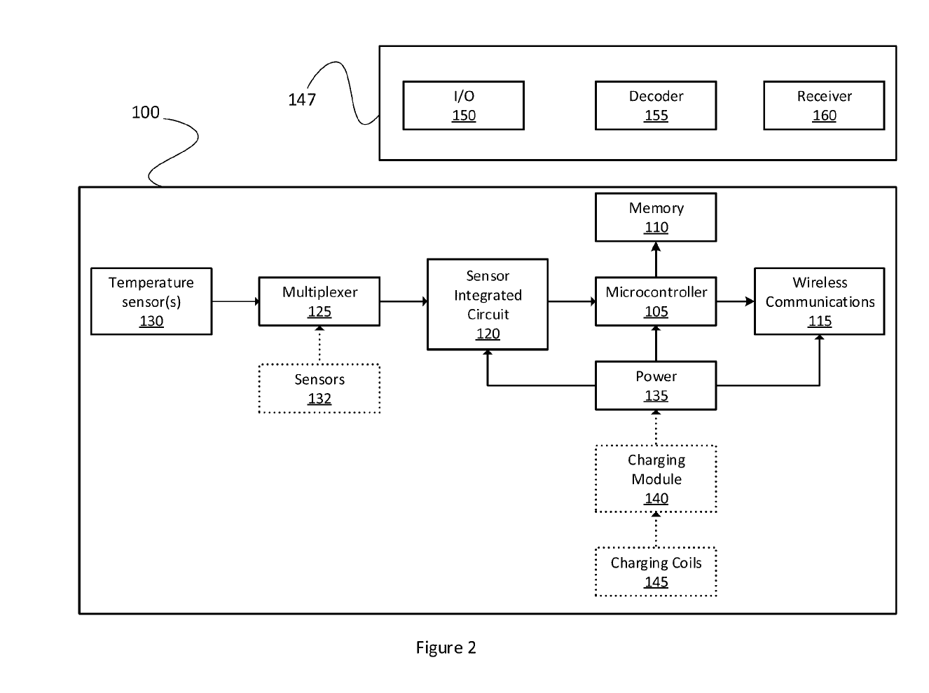

Referring to FIG. 2, a simplified schematic drawing illustrates an electronics package 100 which may include, for instance, one or more sensors 132 (such as temperature sensor(s) 130), a wireless communication module 115, a power source 135, a microcontroller, and an optional on board memory 110. Depending upon the sensors 132, an analog multiplexer 125 and sensor integrated circuit 120 may be included to input the sensor readings into the microcontroller 105. In the example of FIG. 2, the sensors 132 comprise a plurality of temperature sensors 130. The temperature sensors 130 may comprise, for instance, thermocouples (e.g. type-K thermocouples), thermistors, resistance temperature detector (RTD) sensors, or other known temperature sensors. In an aspect, the sensors 132 may include other environmental sensors such as pressure sensors.

The microcontroller 105 may be operative the sample the received sensor readings, and to communicate them in encoded form to a receiver 147 using the wireless communications module 115. The receiver 147 may comprise a receiver module 160 for receiving the wireless communications sent by the wireless communications module 115, a decoder 155 for decoding the received signal, and an I/O module 150 such as a serial, parallel, or other known I/O module.

In an aspect the wireless communications module 115 may comprise a RF transmitter or transceiver. In an aspect, the wireless communications module 115 may comprise an optical transmitter or transceiver. In an implementation, the microcontroller 105 may be operative to sample the received sensor readings, and to store them in the memory store 110. In an aspect, the microcontroller 105 may be operative to store the received sensor readings in the memory store 110 and to transmit them to the receiver 147 using the wireless communication module 115. In an embodiment, the microcontroller 105 may be operative to store the received sensor readings in the memory store 110 during process operations within the process chamber, and to transmit them to the receiver 147 using the wireless communication module 115 when the process chamber measurement wafer 10 is removed from the process chamber. In some embodiments, the process chamber measurement wafer 10 is configured to store data in the memory store 110 if wireless transmission to the receiver 147 is interrupted during the process run.

The power source 135 may comprise, for instance, a battery, capacitor, fuel cell, or other power source 135 capable of powering the electronics package. In an aspect, the power source 135 may comprise a thermal-electric generator that powers the instrumented wafer 15 using the thermal gradient between the exterior surface of the instrumented wafer 15 and the center of the instrumented wafer 15. In an aspect, the power source 135 comprises a rechargeable battery. In an embodiment illustrated in FIG. 2, an optional charging module 140 and charging coils 145 may be incorporated enable wireless charging of the rechargeable battery by induction. The electronics package 100 is located within the payload volume 22 of the instrument package layer 17.

In an implementation, the instrumented wafer 15 is sealed with no open ports. In an aspect, the surface of the instrumented wafer 15 is uniformly ceramic or dielectric, with the exception of only the metal HV connector 20. In rechargeable embodiments, the battery module includes one or more batteries that are charged wirelessly by inductive charging.

Process conditions that may be measured by the instrumented wafer 15 may include, for instance, the temperature and pressure in the process chamber. In some embodiments, temperature is measured at multiple locations across one ore more surfaces of the process chamber measurement wafer 10. In an aspect, the multiple locations may include, at least a top surface and a bottom surface of the instrumented wafer 15. Such embodiments allow for the measurement of temperature on the pedestal and the plasma in the process chamber simultaneously. The process chamber measurement wafer 10 optionally is further configured to assess temperature distribution across at least one surface of the wafer 10 by sampling temperature from a plurality of temperature sensors distributed across the at least one surface of the wafer 10.

In some embodiments, the electronics package 100 is configured to sample and log process conditions (for instance temperature and/or pressure) during operation of the process chamber at pre-determined time intervals. In some aspects, the sample rate of the measurements may be sufficient to provide real-time or near real-time measurements of environmental conditions within the process chamber. In some aspects, the measurements are taken at a plurality of locations across the process chamber measurement wafer 10.

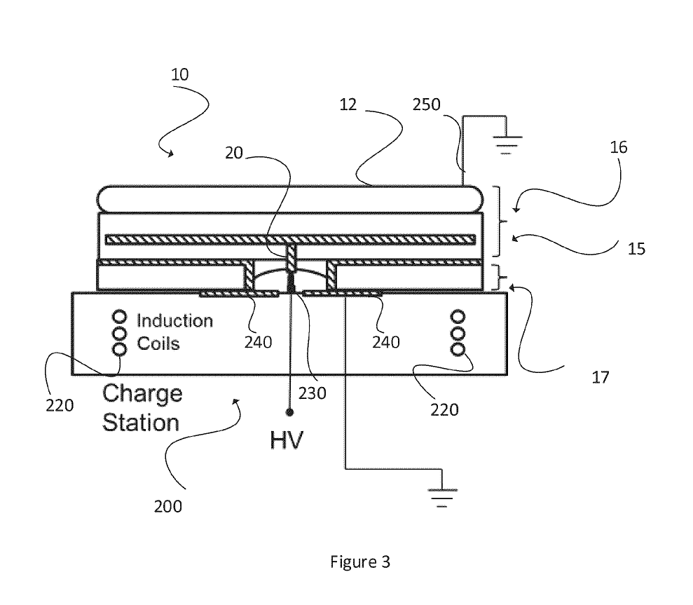

FIG. 3 is a simplified side section view of a charging station 200 that may be used to charge the instrumented wafer 15 described above and illustrated in FIGS. 1 and 2. The charging station 200 include induction coils 220 for energizing the charging module 140 by induction with the complementary charging coils 145 in the instrumented wafer 15. A high voltage supply may be connected by a high voltage connection point 230 that engages with the high voltage connector 20 on the instrumented wafer. Grounding points 240 are situated to engage with exposed portions of the metallized layer 18 to create the grounding plane 18 once grounded. A dummy wafer 12 grounding point 250 is located to ground the dummy wafer 12.

In operation, the charging station 200 is operative to provide the dual function of charging the power source 135 in the electronics package 100, and to energize the electrostatic chuck 21 when electroadhesion is used to secure the dummy wafer 12 to the instrumented wafer 15. Energizing the electrostatic chuck 21, while grounding the dummy wafer 12, secures the dummy wafer 12 to the coupling layer 16 of the instrumented wafer 15. The dummy wafer 12 may be released from the coupling layer 16 by matching the voltage of the electrostatic chuck 21 to the voltage of the dummy wafer 12. The voltage may be matched, for instance, by grounding the high voltage connector 21, to ground the electrostatic chuck 21, removing the voltage differential between the electrostatic chuck 21 and the dummy wafer 12.

Accordingly, prior to a process run, the process chamber measurement wafer 10 may be assembled by locating the instrumented wafer 15 on the charging station 200 to electrically couple the connector 20 to the high voltage connection point 230 and the ground plane 18 to an electrical ground, positioning the dummy wafer 12 on the instrumented wafer 15, and connecting the dummy wafer grounding point 250 to the dummy wafer 12. Energizing the high voltage connection point 230 energizes the electrostatic chuck 21, securing the dummy wafer 12 in place on the instrumented wafer 15 to assemble the process chamber measurement wafer 10. In embodiments where a rechargeable battery is the power source 135, and where charging coils 145 are included in the instrumented wafer 15, the induction coils 220 may be energized to charge the rechargeable battery.

The assembled process chamber measurement wafer 10 may be positioned in the process chamber for one or more process runs. During operation of the process chamber, the process chamber measurement wafer 10 samples the one or more sensors 130 and carries out at least one of storing the sampled sensor samples and transmitting the sampled sensor samples to a receiver 147 outside of the process chamber, as described above.

Once the process run has been completed, the process chamber measurement wafer 10 may be removed from the process chamber. The dummy wafer 12, now coated with material deposited during the process run, may be separated from the instrumented wafer 15 by grounding the high voltage connector 20. In an implementation, the high voltage connector 20 may be grounded by placing the process chamber measurement wafer 10 on the charging station 200. The high voltage connection point 230 being grounded to ground the high voltage connector 20 to release the dummy wafer 12. A replacement dummy wafer 12 may be located on the instrumented wafer 15, and the dummy wafer 12 grounding point 250 connected to the replacement dummy wafer 12. The replacement dummy wafer 12 may be coupled to the instrumented wafer 15 by energizing the high voltage connection point 250, while grounding the dummy wafer 12.

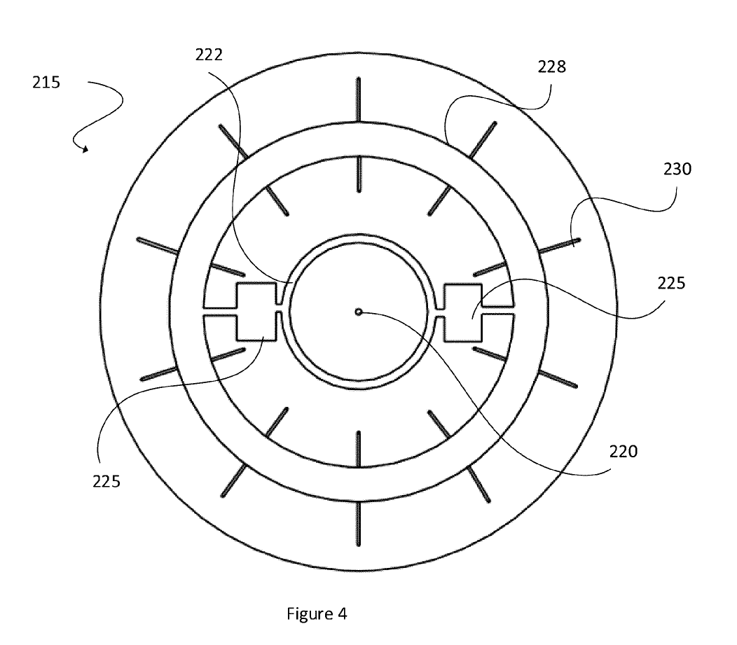

Referring to FIG. 4, a plan section view of an instrument package layer 215 is illustrated. The plan view of FIG. 4 provides an exemplary layout of an embodiment of the instrument package layer 215 for illustrative purposes only. Other layouts are contemplated. Referring to FIG. 4, the instrument package layer 215 includes a high voltage connector 220 for connecting the electrostatic chuck 21 (not seen in this section) to a high voltage source. This embodiment also includes induction coils 222 for charging a battery located, for instance, in one of the two electronics packages 225. A PCB 228 provides connectivity between the electronics packages 225, the power from the induction coils 222, and the sensor traces 230. As indicated above, for instance, the sensor traces 230 may be used to connect sensors such as thermocouples to the electronics packages 225.

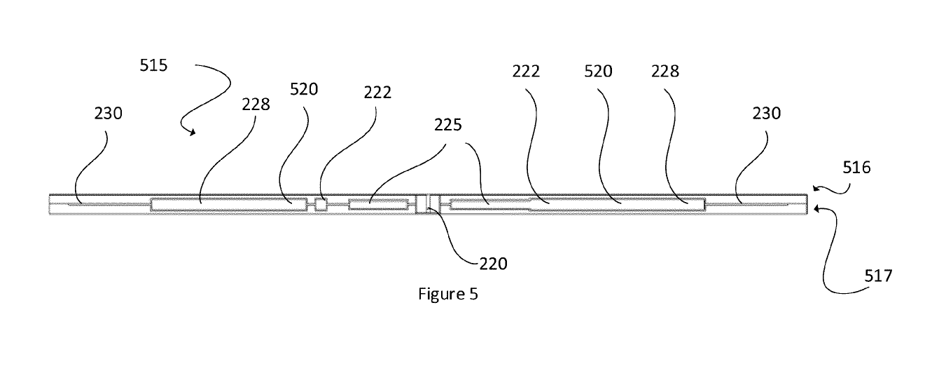

Referring to FIG. 5, an embodiment of a side section view of an instrument package layer 515 is illustrated. As illustrated, the instrument package layer 515 includes an instrumented layer 517 and a coupling layer 516. While not to scale, FIG. 5 provides a better reference for the scale of the various components, where the features of the coupling layer 516 are difficult to discern relative to the features of the instrumented layer 517. In addition to the features illustrated in FIG. 4, the instrument package layer 515 of FIG. 5 further includes thermal electric generators 520 that may be used to generate electrical power from temperature gradients between the top face of the instrument package layer 515 and the bottom surface of the instrument package layer 515. Experimental simulations and studies have shown that, depending upon the particular process dynamics, the instrument package layer 515 may have an internal temperature gradient ranging from 50-500 degrees Celsius. Depending upon the process requirements, a thermal electric generator 520 may be used to power the process measurement device, or may be used to supplement a battery store, contained in the instrument package 225, for instance.

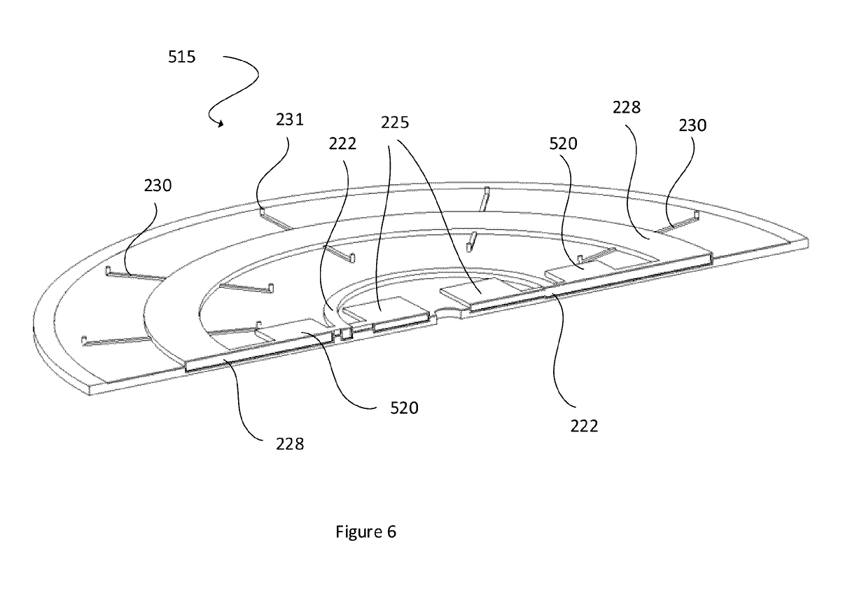

FIG. 6 is an isometric section view of the instrument package layer 515 of FIG. 5. In addition to the features described above, FIG. 6 shows the vertical sensor traces 231 that connect the sensors to the PCB 228. In the case of a thermocouple, for instance, the end of the vertical sensor traces 231 may comprise the sensing element to measure temperature. In FIG. 6 all of the vertical traces 231 are illustrated as extending upward for clarity. In practice, some of the vertical traces 231 may extend either up or down to provide measurement at one of the top face or the bottom face of the instrument package layer 515. In some aspects, the vertical traces 231 may extend both upward and downward at a same location to provide measurements at opposed locations on the opposed top face and bottom face of the instrument package layer 515.

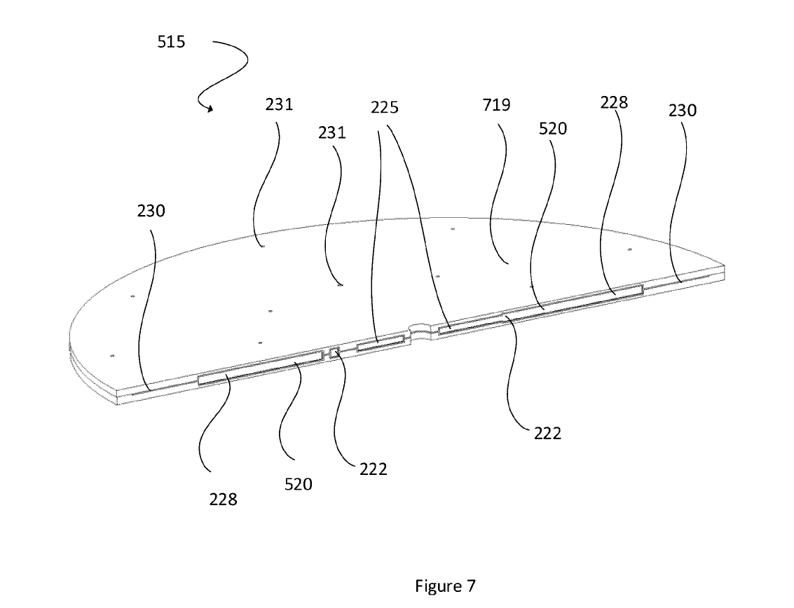

FIG. 7 is an isometric view of the instrument package layer 515 of FIG. 5. In addition to the features described above, the isometric view shows the insulating layer 719 covering the features of FIG. 6. In this embodiment, the vertical traces 231 (or terminating sensing elements) are visible on the surface of the insulating layer 719. In other aspects, a thin layer of dielectric material cover the sensing elements to shield them from the electrostatic chuck 21 when bonded in place.

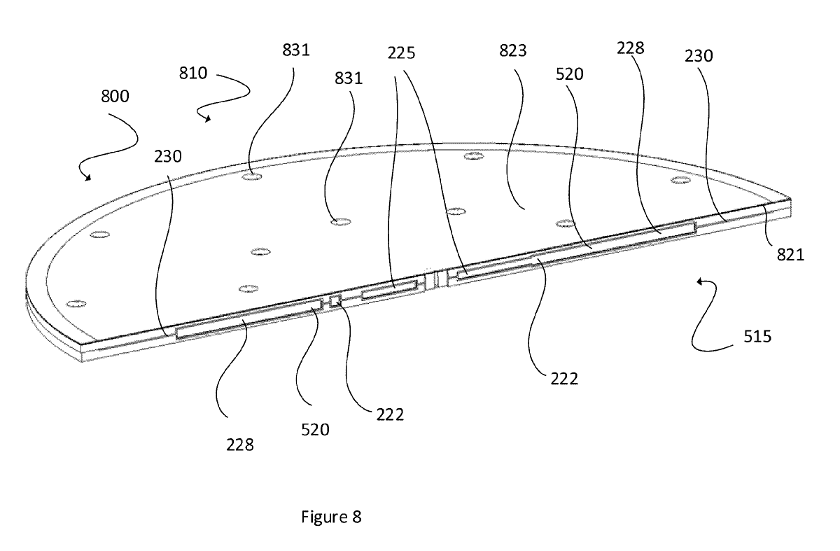

FIG. 8 is an isometric section view of an embodiment of an instrumented wafer 800. The instrumented wafer 800 includes an instrument package layer 515, covered by a coupling layer 810. The top surface of the coupling layer 810 preferably comprises a dielectric layer 823 (e.g. a ceramic coating or sheet). In addition to the features described above, the instrumented wafer 800 include sensor windows 831 to provide exposure for the sensing elements. In some aspects the sensor windows 831 may comprise openings. In some aspects, the sensor windows 831 may comprise a coating or plug applied to cover and seal over the sensing elements. FIG. 8 also includes an electrostatic chuck 821, which is represented by the top heavy line above the instrument package layer 515 at this scale.

Although the invention has been described with reference to certain specific embodiments, various modifications thereof will be apparent to those skilled in the art without departing from the spirit and scope. All such modifications as would be apparent to one skilled in the art are intended to be included within the scope of the following claims.

1. A process chamber measurement wafer comprising:
an instrumented wafer comprising one or more sensors for measuring a process condition of an environment around the instrumented wafer, a coupling layer of the instrumented wafer adapted to releasably secure a releasable protective layer to a top surface of the instrumented wafer.

2. The process chamber measurement wafer of claim 1, wherein the coupling layer is operative to releasably couple the releasable protective layer to the instrumented wafer by electroadhesion.

3. The process chamber measurement wafer of claim 1, wherein the coupling layer includes an electrostatic chuck to releasably secure the releasable protective layer to the top surface.

4. The process chamber measurement wafer of claim 1, wherein the instrumented wafer further comprises a power source.

5. The process chamber measurement wafer of claim 1, wherein the releasable protective layer comprises
dummy wafer.

6. The process chamber measurement wafer of claim 4, wherein the power source comprises a rechargeable battery, and wherein the instrumented wafer further comprises charging coils for inductively charging the rechargeable battery.

7. A process chamber measurement wafer comprising:
a dummy wafer and an instrumented wafer;
wherein the dummy wafer is electrostatically couplable to a coupling layer of the instrumented wafer; and,
wherein the coupling layer comprises a dielectric plate and wherein an instrument package layer of the instrumented wafer comprises one or more sensors, a wireless communication module, and a power source.

8. The process chamber measurement wafer of claim 7, wherein the power source comprises an inductively rechargeable battery.

9. The process chamber measurement wafer of claim 7, wherein the dummy wafer comprises silicon, ceramic or polymer.

10. The process chamber measurement wafer of claim 1, wherein the coupling layer comprising a dielectric plate for electrostatically securing the releasable protective layer over the coupling layer.

11. The process chamber measurement wafer of claim 1, wherein the one or more sensors comprises a plurality of sensors for measuring the process condition from multiple locations on the exterior of the instrumented wafer.

12. The process chamber measurement wafer of claim 1, wherein the process condition comprises temperature.

13. The process chamber measurement wafer of claim 1, wherein the instrument package layer further comprises a microcontroller, a power source, and a wireless communication module.

14. The process chamber measurement wafer of claim 13, wherein the power source comprises a rechargeable battery, and wherein the instrument package layer further comprises an induction coil for charging the rechargeable battery.

15. The process chamber measurement wafer of claim 13, wherein the power source comprises a thermal electric generator for generating power from a temperature gradient between a top surface and a bottom surface of the instrumented wafer.

16. A method of measuring a process condition within a process chamber, comprising:
locating an instrumented wafer to electrically couple a connector of the instrumented wafer to a high voltage supply of the charging station and to electrically couple a ground plane of the instrumented wafer to an electrical ground;
energizing the high voltage supply to electrostatically couple a dummy wafer over a top surface of the instrumented wafer to produce a process chamber measurement wafer;
decoupling the connector from the high voltage supply;
locating the process chamber measurement wafer in a process chamber;
executing a process run of the process chamber, and collecting measurements of at least one process condition within the process chamber using the instrumented wafer;
after the process run has completed, removing the process chamber measurement wafer from the process chamber;
locating the process chamber measurement wafer to electrically couple the connector of the instrumented wafer to the high voltage supply and to electrically couple the ground plane of the instrumented wafer to the electrical ground; and,
matching the voltage of the connector and the ground plane using the charging station to release the dummy wafer from the instrumented wafer.

17. The method of claim 16, wherein the voltage is matched by grounding the connector.

18. The method of claim 16, wherein while the instrumented wafer is electrically coupled to the high voltage supply and the electrical ground, the method further comprises:
inductively charging a rechargeable battery of the instrumented wafer.

19. The method of claim 16, wherein the collecting measurements further comprises:
sampling the at least one process condition; and,
wirelessly transmitting the sampled at least one process condition to a receiver located outside of the process chamber.

20. The process chamber measurement wafer of claim 1, wherein the instrumented wafer further comprises:
an instrument package layer comprising a microcontroller, power source, and wireless communication module; and wherein
a dielectric insulating layer of the instrumented wafer separates the instrument package layer from the coupling layer; and wherein
the coupling layer comprises an electrostatic chuck for releasably securing the releasable protective layer to the top surface.
